(19) United States
(12) Patent Application Publication
(10) Pub. No.: US 2024/0065013 A1
(43) Pub. Date: Feb. 22, 2024

(54) PHOTOELECTRIC CONVERSION ELEMENT, IMAGING APPARATUS, AND METHOD FOR DRIVING PHOTOELECTRIC CONVERSION ELEMENT

(71) Applicant: Panasonic Intellectual Property Management Co., Ltd., Osaka (JP)

(72) Inventors: NOZOMU MATSUKAWA, Nara (JP); SHINICHI MACHIDA, Osaka (JP)

(21) Appl. No.: 18/500,534

(22) Filed: Nov. 2, 2023

Related U.S. Application Data
(63) Continuation of application No. PCT/JP2022/019063, filed on Apr. 27, 2022.

(30) Foreign Application Priority Data
May 24, 2021 (JP) 2021-086919

(51) Int. Cl. H10K 39/32; H10K 30/35; H10K 30/30; H10K 30/87; H10K 85/20

(52) U.S. Cl. CPC H10K 39/32; H10K 30/35; H10K 30/353; H10K 30/87; H10K 85/221; B82Y 20/00

(57) ABSTRACT

A photoelectric conversion element includes a first electrode, a second electrode facing the first electrode, and a photosensitive layer between the first electrode and the second electrode. At least one selected from the group consisting of the first electrode and the second electrode transmits light. The photosensitive layer contains a quantum dot and a semiconducting carbon nanotube that absorbs the light. The quantum dot has a higher absolute value of electron affinity than the semiconducting carbon nanotube.

### BACKGROUND

### 1. Technical Field

The present disclosure relates to a photoelectric conversion element, an imaging apparatus, and a method for driving a photoelectric conversion element.

### 2. Description of the Related Art

A photoelectric conversion element containing a carbon nanotube and a quantum dot in a photoactive layer is known.

Japanese Unexamined Patent Application Publication No. 2011-520262 discloses a photoactive layer composed of a semiconducting carbon nanotube and an organic semiconductor. Japanese Unexamined Patent Application Publication No. 2011-520262 discloses a configuration in which an exciton generated by a semiconducting carbon nanotube absorbing light causes charge separation in a heterojunction with an organic semiconductor.

Japanese Patent No. 6161018 discloses an imaging apparatus composed of a semiconducting carbon nanotube and a substance with a higher electron affinity than the semiconducting carbon nanotube in which the substance with a higher electron affinity collects a negative charge. Japanese Patent No. 6161018 also discloses an imaging apparatus composed of a semiconducting carbon nanotube and a substance with a lower ionization potential than the semiconducting carbon nanotube in which the substance with a lower ionization potential collects a positive charge. Japanese Patent No. 6161018 discloses a material with a fullerene skeleton as a material for collecting an electric charge.

Japanese Unexamined Patent Application Publication No. 2009-531837 discloses an element composed of a carbon nanotube and a photosensitive nanoparticle. More specifically, Japanese Unexamined Patent Application Publication No. 2009-531837 discloses a configuration including a carbon nanotube disposed near a photosensitive nanoparticle to prevent an exciton generated by the photosensitive nanoparticle absorbing light from being annihilated by charge recombination and to increase quantum efficiency. Thus, the high mobility characteristics of a carbon nanotube are used to separate a photosensitive nanoparticle from a separated electric charge, suppress recombination, and improve the quantum efficiency of the photosensitive nanoparticle.

Japanese Unexamined Patent Application Publication No. 2018-529214 discloses a method for growing nanoparticles with a small particle size dispersion and an example of a device using a nanoparticle in a light absorbing layer in a photodetector, a solar cell, or the like. In Japanese Unexamined Patent Application Publication No. 2018-529214, a nanoparticle absorbs light and generates a charge carrier. Japanese Unexamined Patent Application Publication No. 2018-529214 discloses a carbon nanotube as an example of a material for extracting an electron from charge carriers.

International Publication No. WO 2020/121710 discloses a photosensor with a channel layer and a photosensitive layer. In the photosensor disclosed in International Publication No. WO 2020/121710, one of a pair of electric charges generated by the photosensitive layer absorbing light is transported to a drain electrode through the channel layer, and an electric charge is injected from a source electrode to cancel the electric charge remaining in the photosensitive layer, but an electric charge continues to flow from the source electrode to the drain electrode until electric charges in the photosensitive layer are eliminated by recombination. International Publication No. WO 2020/121710 discloses a quantum dot and a carbon nanotube as examples of a material that generates a charge pair upon light absorption.

### SUMMARY

In one general aspect, the techniques disclosed here feature a photoelectric conversion element including a first electrode, a second electrode facing the first electrode, and a photosensitive layer between the first electrode and the second electrode. At least one selected from the group consisting of the first electrode and the second electrode transmits light. The photosensitive layer contains a quantum dot and a semiconducting carbon nanotube that absorbs the light. The quantum dot has a higher absolute value of electron affinity than the semiconducting carbon nanotube.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a schematic view of a cross section of a photoelectric conversion element according to a first embodiment;

FIG. 1B is a schematic view of a magnitude relation of electron affinity between a semiconducting carbon nanotube and a quantum dot according to the first embodiment;

FIG. 2A is a schematic view of a cross section of a photoelectric conversion element according to a second embodiment;

FIG. 2B is a schematic view of a magnitude relation of ionization potential between a semiconducting carbon nanotube and a quantum dot according to the second embodiment;

FIG. 3A is a schematic view of a cross section of a photoelectric conversion element according to a third embodiment;

FIG. 3B is a flowchart of a first example of a method for driving the photoelectric conversion element according to the third embodiment;

FIG. 3C is a flowchart of a second example of the method for driving the photoelectric conversion element according to the third embodiment;

FIG. 4 is a schematic view of a cross section of a photoelectric conversion element according to a modified example of the third embodiment;

FIG. 5 is a view of an example of the circuitry of an imaging apparatus according to a fourth embodiment;

FIG. 6 is a schematic view of a cross section of a device structure of a pixel in the imaging apparatus according to the fourth embodiment;

FIG. 7 is a schematic view of the energy level of each configuration in an Example;

FIG. 8 is a graph of measurement results of spectral sensitivity characteristics of a photoelectric conversion element containing a quantum dot 1 in an Example;

FIG. 9 is a graph of measurement results of spectral sensitivity characteristics of a photoelectric conversion element containing a quantum dot 2 in an Example;

FIG. 10 is a graph of measurement results of spectral sensitivity characteristics of a photoelectric conversion element containing a quantum dot 3 in an Example; and

FIG. 11 is a graph of measurement results of spectral sensitivity characteristics of a photoelectric conversion element containing a quantum dot 4 in an Example.

### DETAILED DESCRIPTIONS

In a known configuration, however, in a photoelectric conversion element that separates and collects an electric charge from an exciton generated by a semiconducting carbon nanotube absorbing light, such as visible light or near-infrared light, only an organic semiconductor or a fullerene derivative is disclosed as a material for extracting the electric charge from the semiconducting carbon nanotube. To change the electron affinity and ionization potential of a fullerene derivative or an organic semiconductor, its molecular skeleton and functional group must be rearranged. At that time, due to a change in the shape of a molecular orbital for extracting an electric charge from a semiconducting carbon nanotube and a change in the state of association between a carbon nanotube and an organic semiconductor, it is not easy to newly synthesize a material optimal for the band structure of the semiconducting carbon nanotube, which changes with the diameter and chirality thereof.

Although a configuration including a combination of a semiconducting carbon nanotube and a quantum dot is disclosed as another known configuration, the semiconducting carbon nanotube is used only as a material for separating an electric charge from the quantum dot or as a material for extracting an electron, or the quantum dot and the semiconducting carbon nanotube are independently used only as a material for generating an electric charge.

The present disclosure provides a photoelectric conversion element or the like that can efficiently use an electric charge generated by a semiconducting carbon nanotube absorbing light.

### Underlying Knowledge Forming Basis of the Present Disclosure

There is a need for a photoelectric conversion element with high sensitivity in the near-infrared region to be used as an imaging apparatus, such as a surveillance camera, a photosensor, or a photoelectric conversion element, such as a solar cell. Thus, the use of a molecule with high sensitivity in the near-infrared region as a photoelectric conversion material of a photoelectric conversion element has been studied. Among the materials with high sensitivity in the near-infrared region, a semiconducting carbon nanotube has the following features.

A molecule of a semiconducting carbon nanotube typically has a tubular shape with a length of tens of nanometers to several millimeters and has unique features that are not found in various known organic materials and inorganic materials. In particular, it is known that a semiconducting carbon nanotube has very high electron and hole mobility. On the other hand, a semiconducting carbon nanotube has a problem in charge extraction from the semiconducting carbon nanotube to use an electric charge generated by light absorption due to high binding energy of a pair of electron and hole, which is an exciton generated by light absorption. It is known that a molecule that transports an electron in an molecular orbital derived from a π electron, such as a fullerene or an organic semiconductor, forms a donor-acceptor bond with a semiconducting carbon nanotube by π-π interaction, and the offset of an orbital level causes charge extraction from the semiconducting carbon nanotube. However, the present inventors have found the following problems in charge extraction from a semiconducting carbon nanotube.

Although a fullerene has high symmetry and, when being close to a semiconducting carbon nanotube, easily forms an overlapping molecular orbital, it is difficult to change the electron affinity and ionization potential of the fullerene. In particular, it is difficult to increase the electron affinity of a fullerene. For example, an increase in wavelength absorbed by a semiconducting carbon nanotube reduces the band gap, relatively increases the electron affinity, and therefore sometimes makes it difficult to extract an electron by a fullerene.

On the other hand, a typical organic semiconductor has molecules with widely different electron affinities and ionization potentials depending on the selected main backbone and functional group, but has low molecular symmetry and has the association state with a semiconducting carbon nanotube independently determined by the shape and the characteristics of the functional group. Thus, an organic semiconductor with a desired electron affinity and ionization potential does not always overlap with a semiconducting carbon nanotube in a molecular orbital and form a donor-acceptor bond.

Furthermore, it is difficult for an organic semiconductor and a fullerene derivative to have stable characteristics due to molecular diffusion by heat, polymerization by light, or bond breakage by light.

The present inventors have newly found from the following findings that a quantum dot with a specific energy level can efficiently extract an electric charge from a semiconducting carbon nanotube. The band gap of a quantum dot can be freely controlled by the particle size. In a quantum dot, the exchange of an electric charge with a ligand modifying the quantum dot surface and the polarization of the ligand can change the ionization potential and shift the entire energy level. Thus, a material of a quantum dot and a ligand can be selected to provide a quantum dot with an ionization potential suitable for extracting a hole from a carbon nanotube. Furthermore, the reaction time and the temperature can be adjusted by an existing quantum dot growth method to continuously control the particle size of a quantum dot, that is, the band gap of the quantum dot. Thus, it is easy to provide a quantum dot with an electron affinity suitable for extracting an electron from a semiconducting carbon nanotube.

The present disclosure has been made on the basis of such findings and provides a photoelectric conversion element or the like that can use a quantum dot as a material for extracting an electric charge from a semiconducting carbon nanotube to efficiently use an electric charge generated by the semiconducting carbon nanotube absorbing light.

An outline of one embodiment of the present disclosure is described below.

A photoelectric conversion element according to one embodiment of the present disclosure includes a first electrode, a second electrode facing the first electrode, and a photosensitive layer between the first electrode and the second electrode. At least one selected from the group consisting of the first electrode and the second electrode transmits light. The photosensitive layer contains a quantum dot and a semiconducting carbon nanotube that absorbs the light. The quantum dot has a higher absolute value of electron affinity than the semiconducting carbon nanotube.

Thus, the quantum dot extracts an electron from a pair of hole and electron generated by the semiconducting carbon nanotube absorbing light. Thus, the hole and electron are separated from each other, and the electric charges can be collected by the first electrode and the second electrode. Furthermore, the electron affinity of the quantum dot can be adjusted by the particle size of the quantum dot and by a ligand modifying the quantum dot surface, and can be easily adjusted. Furthermore, the quantum dot is not easily degraded by heat or light and tends to have stable characteristics. Thus, in the present embodiment, an electric charge generated by the semiconducting carbon nanotube absorbing light can be efficiently used.

A photoelectric conversion element according to another embodiment of the present disclosure includes a first electrode, a second electrode facing the first electrode, and a photosensitive layer between the first electrode and the second electrode. At least one selected from the group consisting of the first electrode and the second electrode transmits light. The photosensitive layer contains a quantum dot and a semiconducting carbon nanotube that absorbs the light. The quantum dot has a lower absolute value of ionization potential than the semiconducting carbon nanotube.

Thus, the quantum dot extracts a hole from a pair of hole and electron generated by the semiconducting carbon nanotube absorbing light. Thus, the hole and electron are separated from each other, and the electric charges can be collected by the first electrode and the second electrode. Furthermore, the ionization potential of the quantum dot can be adjusted by a ligand modifying the quantum dot surface, and can be easily adjusted. Furthermore, the quantum dot is not easily degraded by heat or light and tends to have stable characteristics. Thus, the photoelectric conversion element according to the present embodiment can efficiently utilize an electric charge generated by a semiconducting carbon nanotube absorbing light.

Furthermore, for example, the photosensitive layer may include a quantum dot layer containing the quantum dot, and a semiconducting carbon nanotube layer located between the quantum dot layer and the second electrode and containing the semiconducting carbon nanotube.

Thus, the photosensitive layer has a layered structure in which the quantum dot and the semiconducting carbon nanotube are contained in separate layers, so that the quantum dot and the semiconducting carbon nanotube in the in-plane direction of the photosensitive layer are not localized, and the photoelectric conversion element can have uniform characteristics.

For example, the photosensitive layer may contain a polymer covering the semiconducting carbon nanotube.

This facilitates the use of a semiconducting carbon nanotube with a specific chirality and improves the dispersibility of the semiconducting carbon nanotube in the photosensitive layer.

For example, the semiconducting carbon nanotube in the photosensitive layer may absorb 10% or more of a component with a specific wavelength in the light.

This can increase the photoelectric conversion efficiency of the photoelectric conversion element.

For example, the photoelectric conversion element may further include a charge-blocking layer between the first electrode or the second electrode and the photosensitive layer.

The charge-blocking layer can reduce the injection of an electric charge from an electrode to the photosensitive layer and reduce the dark current.

For example, the photoelectric conversion element may have an external quantum efficiency of 10% or more at a light absorption peak wavelength of the semiconducting carbon nanotube. The photoelectric conversion element may have an external quantum efficiency of 30% or more at a light absorption peak wavelength of the semiconducting carbon nanotube.

This makes it possible to realize a high photoelectric conversion efficiency due to the light absorption of the semiconducting carbon nanotube.

An imaging apparatus according to an embodiment of the present disclosure includes a plurality of pixels, and each of the plurality of pixels includes the photoelectric conversion element.

Thus, each of the plurality of pixels in the imaging apparatus has the photoelectric conversion element, and the imaging apparatus can therefore efficiently use an electric charge generated by a semiconducting carbon nanotube absorbing light.

A method for driving a photoelectric conversion element according to an embodiment of the present disclosure is a method for driving the photoelectric conversion element described above, wherein the photosensitive layer includes a quantum dot layer containing the quantum dot, and a semiconducting carbon nanotube layer located between the quantum dot layer and the second electrode and containing the semiconducting carbon nanotube. The driving method includes: setting the electric potential of the first electrode to be positive with respect to the electric potential of the second electrode; and out of an electron and a hole generated by the semiconducting carbon nanotube absorbing light, collecting the electron through the quantum dot using the first electrode and collecting the hole using the second electrode.

Thus, the quantum dot extracts an electron from a pair of hole and electron generated by the semiconducting carbon nanotube absorbing light, and the hole remains in the semiconducting carbon nanotube. The electron extracted by the quantum dot is transported in the quantum dot layer and is collected by the first electrode. The hole remaining in the semiconducting carbon nanotube is transported in the semiconducting carbon nanotube layer and is collected by the second electrode. This reduces the potential variance during the transport of an electric charge, and the electric charge is smoothly transported to the electrode. Thus, in the present embodiment, an electric charge generated by the semiconducting carbon nanotube absorbing light can be efficiently used.

A method for driving a photoelectric conversion element according to an embodiment of the present disclosure is a method for driving the photoelectric conversion element described above, wherein the photosensitive layer includes a quantum dot layer containing the quantum dot, and a semiconducting carbon nanotube layer located between the quantum dot layer and the second electrode and containing the semiconducting carbon nanotube. The driving method includes: setting the electric potential of the first electrode to be negative with respect to the electric potential of the second electrode; and out of an electron and a hole generated by the semiconducting carbon nanotube absorbing light, collecting the hole through the quantum dot using the first electrode and collecting the electron using the second electrode.

Thus, the quantum dot extracts a hole from a pair of hole and electron generated by the semiconducting carbon nanotube absorbing light, and the electron remains in the semiconducting carbon nanotube. The hole extracted by the quantum dot is transported in the quantum dot layer and is collected by the first electrode. The electron remaining in the semiconducting carbon nanotube is transported in the semiconducting carbon nanotube layer and is collected by the second electrode. This reduces the potential variance during the transport of an electric charge, and the electric charge is smoothly transported to the electrode. Thus, in the present embodiment, an electric charge generated by the semiconducting carbon nanotube absorbing light can be efficiently used.

Embodiments of the present disclosure are described below with reference to the accompanying drawings.

It should be noted that the embodiments described below are general or specific examples. The numerical values, shapes, components, arrangement and connection of the components, steps, sequential order of steps, and the like in the following embodiments are only examples and are not intended to limit the present disclosure. Among the components in the following embodiments, components not described in the independent claims are described as optional components. Furthermore, the figures are not necessarily precise figures. Thus, for example, the scale of each figure is not necessarily the same. Like parts are denoted by like reference numerals throughout the figures. Parts once described are sometimes not described again or are sometimes simply described.

In the present specification, terms describing the relationship between elements, terms describing the shape of an element, and numerical ranges not only refer to their exact meanings but also to substantially the equivalent meanings. For example, numerical ranges tolerate variations of several percent.

The terms “above” and “below”, as used herein, do not necessarily indicate upward (vertically upward) and downward (vertically downward) in the sense of absolute spatial perception but indicates the relative positional relationship based on the stacking sequence in a multilayer structure. The terms, such as “above” and “below”, are used to specify the mutual arrangement of members and are not intended to limit the posture during the use of an imaging apparatus. The terms “above” and “below” are applied not only to the case where two constituents are spaced apart from each other and another constituent is located between the two constituents but also to the case where two constituents are closely located from each other and are in contact with each other.

The terms “high” and “low” in the comparison of electron affinity, ionization potential, work function, and the like, as used herein, refer to “high” and “low” in the comparison of absolute values of electron affinity, ionization potential, work function, and the like.

In the present specification, all electromagnetic waves, including visible light, infrared light, and ultraviolet light, are referred to as “light” for convenience.

### First Embodiment

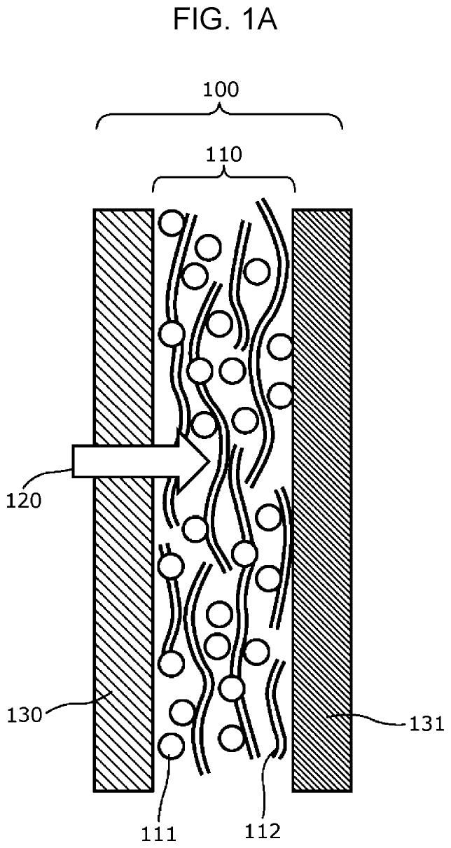

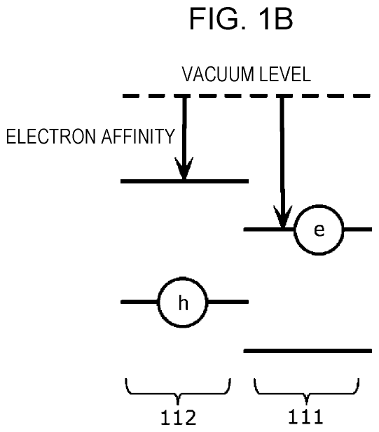

FIG. 1A is a schematic view of a cross section of a photoelectric conversion element according to a first embodiment. FIG. 1B is a schematic view of a magnitude relation of electron affinity between a semiconducting carbon nanotube and a quantum dot according to the first embodiment.

As illustrated in FIG. 1A, a photoelectric conversion element 100 includes an electrode 130, an electrode 131 facing the electrode 130, and a photosensitive layer 110 located between the electrode 130 and the electrode 131. The electrode 130 is an example of a first electrode, and the electrode 131 is an example of a second electrode. The photoelectric conversion element 100 may include a charge-blocking layer described later between at least one of the electrode 130 and the electrode 131 and the photosensitive layer 110.

The electrodes 130 and 131 are, for example, film electrodes. A bias voltage is applied to the electrodes 130 and 131, for example, by wiring (not shown). For example, the polarity of the bias voltage is determined such that an electron of a pair of electron and hole generated in the photosensitive layer 110 moves to the electrode 130 and the hole moves to the electrode 131. The bias voltage may be set such that a hole of a pair of electron and hole generated in the photosensitive layer 110 moves to the electrode 130 and the electron moves to the electrode 131.

At least one of the electrodes 130 and 131 transmits at least light of a specific wavelength. The specific wavelength is a wavelength absorbed by a semiconducting carbon nanotube 112 described later, for example, a light absorption peak wavelength of the semiconducting carbon nanotube 112. Furthermore, at least one of the electrodes 130 and 131 may transmit light in a wavelength range including a wavelength range in which the semiconducting carbon nanotube 112 substantially has an absorption intensity. In the present specification, transmission of light of a certain wavelength means, for example, that the transmittance of light of the certain wavelength is 50% or more and may be 70% or more. Among the electrodes 130 and 131, the electrode 130 transmits light of a specific wavelength in the following description, but the electrode 131 may transmit light of a specific wavelength. Both the electrodes 130 and 131 may transmit light of a specific wavelength.

The electrode 130 is made of a material that transmits, for example, visible light to near-infrared light in order to transmit light with a wavelength absorbed by the semiconducting carbon nanotube 112. The material that transmits visible light to near-infrared light is, for example, a transparent conducting oxide (TCO), such as indium tin oxide (ITO) or aluminum zinc oxide (AZO), a silver nanowire, graphene, or a metallic carbon nanotube. The electrode 130 may be made of a material that transmits only near-infrared light. The material that transmits only near-infrared light is, for example, a semiconductor material with a band gap wider than a desired wavelength, such as doped silicon. These materials may be used for the electrode 131.

The material of the electrode 131 is, for example, a metal, such as aluminum, gold, or copper, an electrically conductive metal compound, such as titanium nitride or tungsten nitride, or a transparent conductive oxide, such as ITO. These materials may be used for the electrode 130.

The photosensitive layer 110 includes a quantum dot 111 and the semiconducting carbon nanotube 112. The quantum dot 111 and the semiconducting carbon nanotube 112 are dispersed in the photosensitive layer 110. The semiconducting carbon nanotube 112 absorbs light 120 and generates an exciton composed of a pair of electron and hole. The exciton diffuses through the semiconducting carbon nanotube 112 during the lifetime thereof, and the electron of the exciton is extracted by the quantum dot 111 at the interface between the quantum dot 111 and the semiconducting carbon nanotube 112. More specifically, as illustrated in FIG. 1B, the quantum dot 111 has a higher electron affinity than the semiconducting carbon nanotube 112. Thus, an electron of a pair of hole and electron that is an exciton generated by the semiconducting carbon nanotube 112 absorbing the light 120 is extracted by the quantum dot 111 at the interface between the quantum dot 111 and the semiconducting carbon nanotube 112, and the hole remains in the semiconducting carbon nanotube 112. Depending on the dispersion state of the quantum dot 111 and the semiconducting carbon nanotube 112, a hole and an electron move to the electrodes 130 and 131. When a bias voltage is applied from the outside so that the electrode 130 has a higher work function than the electrode 131 or so that the electrode 130 has a positive electric potential with respect to the electrode 131, an electron moves to the electrode 130, and a hole moves to the electrode 131. When a bias voltage is applied from the outside so that the electrode 130 has a lower work function than the electrode 131 or so that the electrode 130 has a negative electric potential with respect to the electrode 131, an electron may move to the electrode 131, and a hole may move to the electrode 130.

The electron affinity of the quantum dot 111 is, for example, lower than the ionization potential of the semiconducting carbon nanotube 112. The difference between the electron affinity of the quantum dot 111 and the electron affinity of the semiconducting carbon nanotube 112 is, for example, smaller than the difference between the electron affinity of the quantum dot 111 and the ionization potential of the semiconducting carbon nanotube 112. This results in the interaction between the valence band of the quantum dot 111 and the conduction band of the semiconducting carbon nanotube 112 smaller than the interaction between the valence band of the quantum dot 111 and the valence band of the semiconducting carbon nanotube 112 and can increase the photoelectric conversion efficiency.

The quantum dot 111 is a material that has a three-dimensional quantum confinement effect. The quantum dot 111 is a nanocrystal with a diameter smaller than the Bohr radius of an exciton of a material constituting the quantum dot and often with a diameter in the range of approximately 2 nm to 10 nm. A material of the quantum dot 111 is, for example, a group IV semiconductor, such as Si or Ge, a group IV-VI semiconductor, such as PbS, PbSe, or PbTe, a group III-V semiconductor, such as InAs or InSb, or a ternary mixed crystal, such as HgCdTe or PbSnTe. A material of the quantum dot 111 includes, for example, at least one of CdSe, CdS, PbS, PbSe, ZnO, ZnS, Cu₂ZnSnS₄ (CZTS), Cu₂S, Bi₂S₃, Ag₂S, HgTe, CdHgTe, InAs, and InSb.

The surface of the quantum dot 111 is modified with a ligand. The surface of an available quantum dot is often modified with a ligand having a long-chain alkyl to increase dispersibility during synthesis. A ligand with a long-chain alkyl inhibits charge transfer. Thus, as a ligand for modifying the surface of the quantum dot 111, for example, a ligand with a long-chain alkyl is substituted with a ligand of a short molecule, a semiconducting ligand with a π bond, an atom ligand, such as a halide ion, or the like. The substitution method may be an existing method, such as a solid-phase substitution method of forming a film (solid phase) from a quantum dot and then exposing the film to a solution of a substituting ligand for substitution by the concentration and by the difference in binding energy between the ligands, or a liquid-phase substitution method of substituting a ligand in a solution (liquid phase). The solid-phase substitution method is widely applicable because it is not restricted by solution dispersibility after substitution. In the solid-phase substitution method, the film thickness that can be substituted is limited by the diffusion length of the ligand in the thin film, and the thin film formation and the solid-phase substitution are repeated to achieve a desired film thickness. In the liquid-phase substitution, a thin film can be formed after the substitution of the ligand. The liquid-phase substitution should be performed under conditions where stable dispersion in the solution is achieved after the substitution, and the combination of the quantum dot, the ligand, and the solvent that can be applied may be limited.

The ionization potential of the quantum dot 111 can be controlled by the exchange of electric charges between the quantum dot 111 and the ligand and by the polarization of the ligand. For example, more positive polarization on the side of the ligand opposite the quantum dot 111 side (that is, on the front side of the complex of the quantum dot 111 and the ligand that modifies the surface of the quantum dot 111) results in lower ionization potential. The band gap of the quantum dot 111 can be controlled by the particle size of the quantum dot 111. For example, the quantum dot 111 with a larger particle size has a narrower band gap. Thus, the quantum dot 111 with a larger particle size has a longer light absorption peak wavelength. The band gap corresponds to the difference between the ionization potential and the electron affinity. Thus, the particle size and the ligand of the quantum dot 111 can be appropriately determined to easily provide the photosensitive layer 110 containing the quantum dot 111 with a higher electron affinity than the semiconducting carbon nanotube 112.

A specific ligand is, for example, an organic compound, such as tetrabutylammonium halide, 1,2-ethanedithiol, or 1,4-benzenedithiol, or an inorganic compound, such as lead halide or zinc halide. When an inorganic compound is used as a ligand, it may be used in combination with an organic compound, such as mercaptopropionic acid.

As described above, in the quantum dot 111, the light absorption peak wavelength depends on the particle size, and the particle size of the quantum dot can therefore also be expressed by the light absorption peak wavelength. More specifically, the quantum dot with a longer light absorption peak wavelength has a larger particle size, and the quantum dot with a shorter light absorption peak wavelength has a smaller particle size.

The quantum dot 111, for example, has a substantially uniform particle size and has one absorption peak in the near-infrared region. The quantum dot 111 may have a plurality of absorption peaks in the near-infrared region.

The semiconducting carbon nanotube 112 absorbs light of a specific wavelength passing through the electrode 130. An absorption wavelength of the semiconducting carbon nanotube 112 is determined by the chirality. The semiconducting carbon nanotube 112 has a plurality of light absorption peaks determined by the chirality. A specific wavelength of light passing through the electrode 130 is, for example, a light absorption peak wavelength on the longest side among a plurality of light absorption peaks determined by the chirality. The semiconducting carbon nanotube 112 may be composed of a mixture of semiconducting carbon nanotubes with a plurality of different chiralities or may be composed of a semiconducting carbon nanotube with a single chirality. The semiconducting carbon nanotube 112 is composed of, for example, semiconducting carbon nanotubes with three or less types of chirality. When the semiconducting carbon nanotube 112 has a limited type of chirality, a steep light absorption peak corresponding to the chirality can be used.

The semiconducting carbon nanotube 112 absorbs, for example, 10% or more of a component with a specific wavelength in light passing through the electrode 130. The semiconducting carbon nanotube 112 may absorb 30% or more or 50% or more of a component with a specific wavelength in light passing through the electrode 130. The thickness of the photosensitive layer 110 and the concentration of the semiconducting carbon nanotube 112 in the photosensitive layer 110 are adjusted to contain the semiconducting carbon nanotube 112, for example, in an amount that provides such absorption characteristics in the photosensitive layer 110. This can increase the photoelectric conversion efficiency of the photoelectric conversion element 100.

The photoelectric conversion element 100 may have an external quantum efficiency of 10% or more or 30% or more at a light absorption peak wavelength of the semiconducting carbon nanotube 112, for example, at least one of a plurality of light absorption peak wavelengths of the semiconducting carbon nanotube 112.

A carbon nanotube synthesized by a typical synthesis method is a mixture of a metallic carbon nanotube and a semiconducting carbon nanotube. A metallic carbon nanotube promotes the recombination of excitons and causes a short circuit between electrodes. Thus, a semiconducting carbon nanotube extracted from a mixture of a metallic carbon nanotube and a semiconducting carbon nanotube is used for the photosensitive layer 110.

A semiconducting carbon nanotube can be extracted from a mixture of a metallic carbon nanotube and a semiconducting carbon nanotube by an existing techniques, such as density gradient centrifugation, gel filtration, electrophoresis, or separation by mixing with a specific polymer. In particular, the separation by mixing with a specific polymer can reduce aggregation in an organic solvent simultaneously with the extraction of a semiconducting carbon nanotube, thereby facilitating the formation of the element. In the separation by mixing with a specific polymer, a carbon nanotube and the polymer are mixed in a solvent and are subjected to ultrasonic homogenizer treatment and centrifugation treatment to extract a semiconducting carbon nanotube covered with the polymer. Furthermore, a certain polymer selectively wraps around a semiconducting carbon nanotube with a specific chirality, covers the semiconducting carbon nanotube, and can therefore be used to extract the semiconducting carbon nanotube with the specific chirality.

The photosensitive layer 110 may include a polymer covering the semiconducting carbon nanotube 112. That is, the semiconducting carbon nanotube 112 may be the semiconducting carbon nanotube 112 extracted using the separation by mixing with a specific polymer, as described above. This allows a semiconducting carbon nanotube with a specific chirality to be easily used as the semiconducting carbon nanotube 112 and improves the dispersibility of the semiconducting carbon nanotube 112 in the photosensitive layer 110. The polymer is, for example, a semiconducting polymer with a repeating unit containing a moiety with π-electronic properties. The semiconducting polymer is, for example, π-electron conjugated polymer with a planar monomer backbone, such as a polymer of fluorene, a fluorene derivative, thiophene, a thiophene derivative, or a phenylenevinylene derivative.

The photosensitive layer 110 is formed, for example, by depositing a dispersion liquid containing the quantum dot 111 and the semiconducting carbon nanotube 112 prepared as described above on one of the electrodes 130 and 131 by spin coating or another method. The other of the electrodes 130 and 131 is then formed on the photosensitive layer 110 to produce the photoelectric conversion element 100.

As described above, in the photoelectric conversion element 100, an electron of a pair of hole and electron generated in the semiconducting carbon nanotube 112 is extracted by the quantum dot 111 adjusted to have an appropriate electron affinity. This separates the hole and the electron and allows the electric charges to be collected by the electrodes 130 and 131. Furthermore, the electron affinity of the quantum dot 111 can be adjusted by the particle size of the quantum dot 111 and by the ligand that modifies the surface of the quantum dot 111, and can be easily adjusted. Thus, the photoelectric conversion element 100 can efficiently use an electric charge generated by the semiconducting carbon nanotube 112 absorbing light.

### Second Embodiment

Next, a photoelectric conversion element according to a second embodiment is described below. In the following description of the second embodiment, points of difference from the first embodiment are mainly described, and common features are not described or simply described.

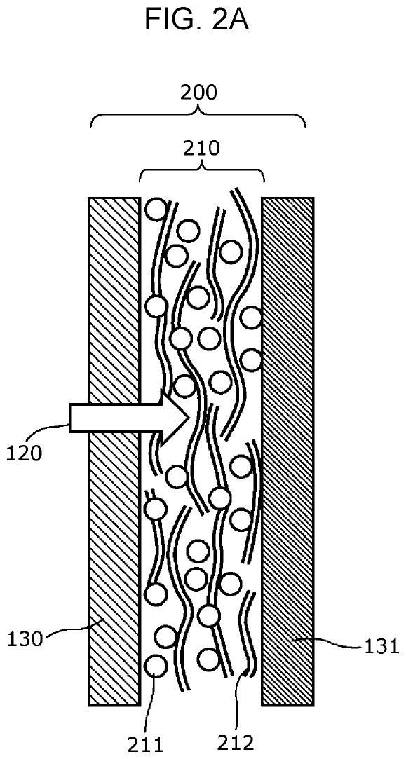

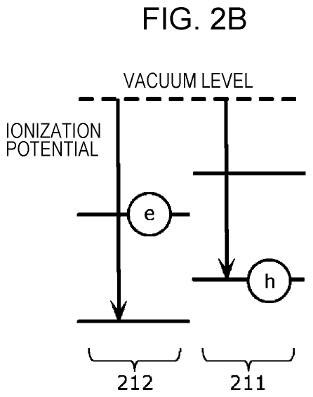

FIG. 2A is a schematic view of a cross section of a photoelectric conversion element according to the second embodiment. FIG. 2B is a schematic view of a magnitude relation of ionization potential between a semiconducting carbon nanotube and a quantum dot according to the second embodiment.

As illustrated in FIG. 2A, a photoelectric conversion element 200 according to the second embodiment is different from the photoelectric conversion element 100 according to the first embodiment in that a photosensitive layer 210 is provided instead of the photosensitive layer 110.

The photosensitive layer 210 includes a quantum dot 211 and a semiconducting carbon nanotube 212. The quantum dot 211 and the semiconducting carbon nanotube 212 are dispersed in the photosensitive layer 210. As illustrated in FIG. 2B, the quantum dot 211 has a lower ionization potential than the semiconducting carbon nanotube 212. Thus, a hole of a pair of hole and electron that is an exciton generated by the semiconducting carbon nanotube 212 absorbing the light 120 is extracted by the quantum dot 211 at the interface between the quantum dot 211 and the semiconducting carbon nanotube 212, and the electron remains in the semiconducting carbon nanotube 212. Depending on the dispersion state of the quantum dot 211 and the semiconducting carbon nanotube 212, a hole and an electron move to the electrodes 130 and 131. When a bias voltage is applied from the outside so that the electrode 130 has a higher work function than the electrode 131 or so that the electrode 130 has a positive electric potential with respect to the electrode 131, an electron moves to the electrode 130, and a hole moves to the electrode 131. When a bias voltage is applied from the outside so that the electrode 130 has a lower work function than the electrode 131 or so that the electrode 130 has a negative electric potential with respect to the electrode 131, an electron may move to the electrode 131, and a hole may move to the electrode 130.

The ionization potential of the quantum dot 211 is, for example, higher than the electron affinity of the semiconducting carbon nanotube 212. The difference between the ionization potential of the quantum dot 211 and the ionization potential of the semiconducting carbon nanotube 212 is, for example, smaller than the difference between the ionization potential of the quantum dot 211 and the electron affinity of the semiconducting carbon nanotube 212. This results in the interaction between the conduction band of the quantum dot 211 and the valence band of the semiconducting carbon nanotube 212 smaller than the interaction between the conduction band of the quantum dot 211 and the conduction band of the semiconducting carbon nanotube 212 and can increase the photoelectric conversion efficiency.

The quantum dot 211 and the semiconducting carbon nanotube 212 are the same as the quantum dot 111 and the semiconducting carbon nanotube 112 except for the magnitude relation of the ionization potential and the like, and are therefore not described in detail here.

As described above, in the photoelectric conversion element 200, a hole of a pair of hole and electron generated in the semiconducting carbon nanotube 212 is extracted by the quantum dot 211 adjusted to have an appropriate ionization potential. This separates the hole and the electron and allows the electric charges to be collected by the electrodes 130 and 131. Furthermore, the ionization potential of the quantum dot 211 can be adjusted by a ligand modifying the quantum dot 211 surface, and can be easily adjusted. Thus, the photoelectric conversion element 200 can efficiently use an electric charge generated by the semiconducting carbon nanotube 212 absorbing light.

The photoelectric conversion element 200 may include a charge-blocking layer described later between at least one of the electrodes 130 and 131 and the photosensitive layer 210.

### Third Embodiment

Next, a photoelectric conversion element according to a third embodiment is described below. In the following description of the third embodiment, points of difference from the first embodiment and the second embodiment are mainly described, and common features are not described or simply described.

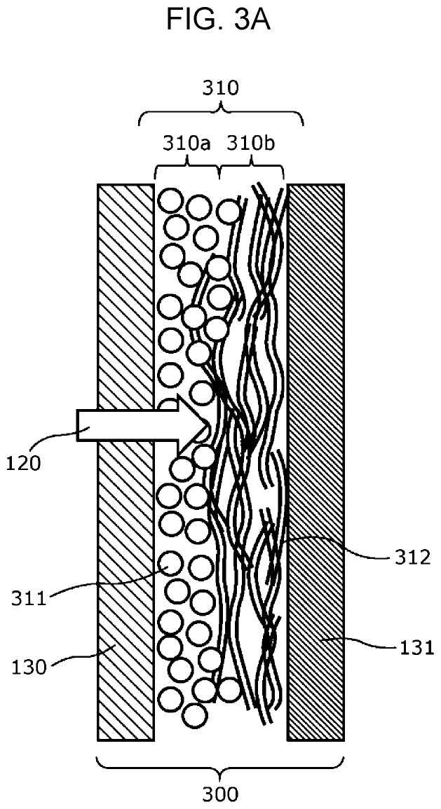

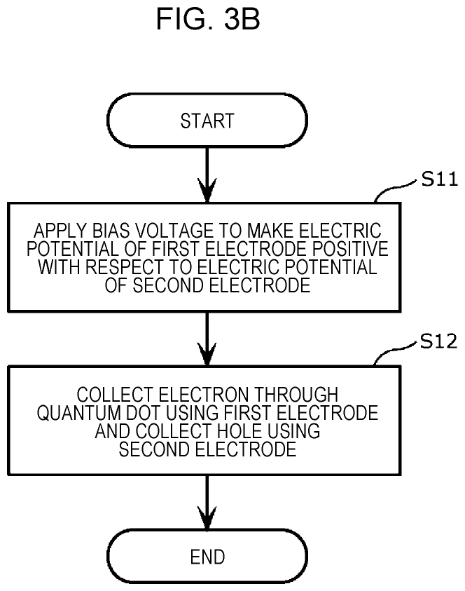

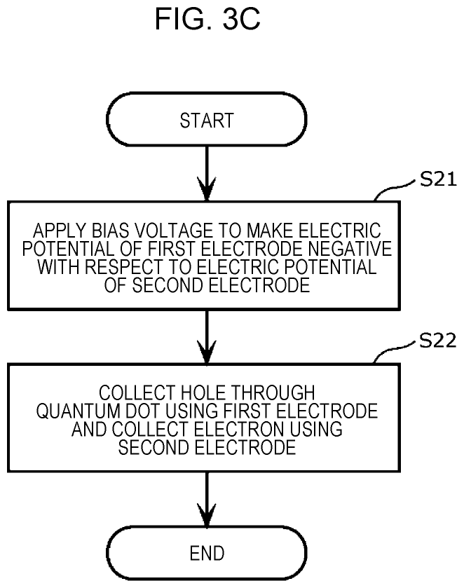

FIG. 3A is a schematic view of a cross section of a photoelectric conversion element according to the third embodiment.

As illustrated in FIG. 3A, a photoelectric conversion element 300 according to the third embodiment is different from the photoelectric conversion element 100 according to the first embodiment in that a photosensitive layer 310 is provided instead of the photosensitive layer 110.

The photosensitive layer 310 has a layered structure of a quantum dot 311 and a semiconducting carbon nanotube 312. More specifically, the photosensitive layer 310 has a quantum dot layer 310a containing the quantum dot 311 and a semiconducting carbon nanotube layer 310b containing the semiconducting carbon nanotube 312. The quantum dot layer 310a is in contact with the semiconducting carbon nanotube layer 310b. The quantum dot layer 310a is located between the electrode 130 and the semiconducting carbon nanotube layer 310b. The semiconducting carbon nanotube layer 310b is located between the electrode 131 and the quantum dot layer 310a. That is, the photosensitive layer 310 has a structure in which the quantum dot layer 310a and the semiconducting carbon nanotube layer 310b are stacked in this order from the electrode 130 side. Thus, the photosensitive layer 310 has a layered structure in which the quantum dot 311 and the semiconducting carbon nanotube 312 are contained in separate layers, so that the quantum dot 311 and the semiconducting carbon nanotube 312 in the in-plane direction of the photosensitive layer 310 are not localized, and the photoelectric conversion element 300 can have uniform characteristics. Furthermore, the quantum dot layer 310a and the semiconducting carbon nanotube layer 310b can be separately formed, and the photosensitive layer 310 can therefore be stably formed.

For example, the quantum dot 311 and the semiconducting carbon nanotube 312 are the same as the quantum dot 111 and the semiconducting carbon nanotube 112 according to the first embodiment. That is, the quantum dot 311 may have a higher electron affinity than the semiconducting carbon nanotube 312.

For example, the quantum dot 311 and the semiconducting carbon nanotube 312 are the same as the quantum dot 211 and the semiconducting carbon nanotube 212 according to the second embodiment. That is, the quantum dot 311 may have a lower ionization potential than the semiconducting carbon nanotube 312.

Next, an example of a method for driving the photoelectric conversion element 300 is described below.

First, a first example of the method for driving the photoelectric conversion element 300 is described below. FIG. 3B is a flowchart of the first example of the method for driving the photoelectric conversion element 300. FIG. 3B is a driving method when the quantum dot 311 has a higher electron affinity than the semiconducting carbon nanotube 312.

First, the electric potential of the electrode 130 serving as the first electrode is made positive with respect to the electric potential of the electrode 131 serving as the second electrode. For example, a voltage supply circuit or the like is used to apply a bias voltage that makes the electric potential of the electrode 130 positive with respect to the electric potential of the electrode 131 between the electrode 130 and the electrode 131 (step S11).

Next, an electron of a pair of hole and electron generated by the semiconducting carbon nanotube 312 absorbing the light 120 is collected by the electrode 130 serving as the first electrode through the quantum dot 311, and the hole is collected by the electrode 131 serving as the second electrode (step S12). More specifically, an electron of a pair of hole and electron generated by the semiconducting carbon nanotube 312 of the semiconducting carbon nanotube layer 310b absorbing the light 120 is extracted by the quantum dot 311 of the quantum dot layer 310a, and the hole remains in the semiconducting carbon nanotube 312 of the semiconducting carbon nanotube layer 310b. The electron extracted by the quantum dot 311 is transported in the quantum dot layer 310a and is collected by the electrode 130. The hole remaining in the semiconducting carbon nanotube 312 is transported in the semiconducting carbon nanotube layer 310b and is collected by the electrode 131.

Next, a second example of the method for driving the photoelectric conversion element 300 is described below. FIG. 3C is a flowchart of the second example of the method for driving the photoelectric conversion element 300. FIG. 3C shows a driving method when the quantum dot 311 has a lower ionization potential than the semiconducting carbon nanotube 312.

First, the electric potential of the electrode 130 serving as the first electrode is made negative with respect to the electric potential of the electrode 131 serving as the second electrode. For example, a voltage supply circuit or the like is used to apply a bias voltage that makes the electric potential of the electrode 130 negative with respect to the electric potential of the electrode 131 between the electrode 130 and the electrode 131 (step S21).

Next, a hole of a pair of hole and electron generated by the semiconducting carbon nanotube 312 absorbing the light 120 is collected by the electrode 130 serving as the first electrode through the quantum dot 311, and the electron is collected by the electrode 131 serving as the second electrode (step S22). More specifically, a hole of a pair of hole and electron generated by the semiconducting carbon nanotube 312 of the semiconducting carbon nanotube layer 310b absorbing the light 120 is extracted by the quantum dot 311 of the quantum dot layer 310a, and the electron remains in the semiconducting carbon nanotube 312 of the semiconducting carbon nanotube layer 310b. The hole extracted by the quantum dot 311 is transported in the quantum dot layer 310a and is collected by the electrode 130. The electron remaining in the semiconducting carbon nanotube 312 is transported in the semiconducting carbon nanotube layer 310b and is collected by the electrode 131.

As in the first example of the driving method and the second example of the driving method, in the photoelectric conversion element 300, the photosensitive layer 310 has the layered structure of the quantum dot layer 310a and the semiconducting carbon nanotube layer 310b, and an electric charge is therefore transported in the quantum dot layer 310a and the semiconducting carbon nanotube layer 310b. This reduces the potential variance during the transport of an electric charge, and the electric charge is smoothly transported to the electrodes 130 and 131. On the other hand, although the interface where the quantum dot 311 is in contact with the semiconducting carbon nanotube 312 is limited, the resonance level of the semiconducting carbon nanotube 312 has a high absorption coefficient, even a thin film can absorb a large amount of light, and the exciton diffusion length in the semiconducting carbon nanotube layer 310b is much longer than that of a typical organic semiconductor. Thus, even the layered structure can have high photoresponse sensitivity.

The photoelectric conversion element 100 according to the first embodiment may be operated in the same manner as in the first example of the driving method. The photoelectric conversion element 200 according to the second embodiment may be operated in the same manner as in the second example of the driving method.

### Modified Example

Next, a photoelectric conversion element according to a modified example of the third embodiment is described below. In the following description of the modified example of the third embodiment, points of difference from the first to third embodiments are mainly described, and common features are not described or simply described.

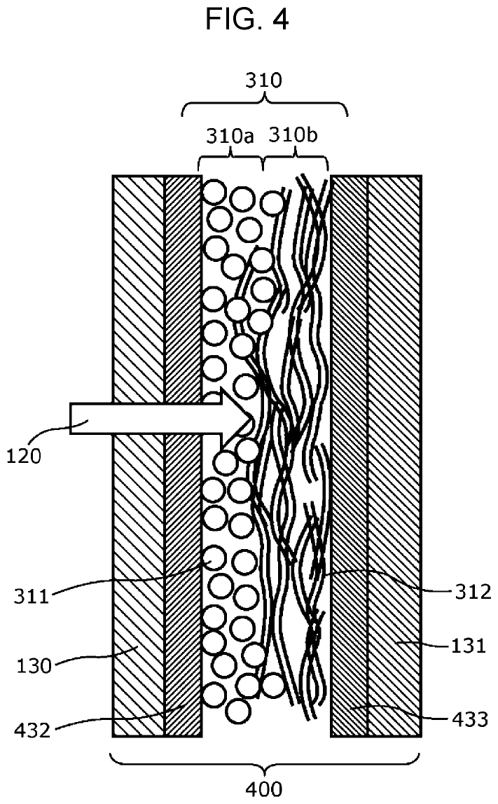

FIG. 4 is a schematic view of a cross section of a photoelectric conversion element according to the modified example of the third embodiment.

As illustrated in FIG. 4, a photoelectric conversion element 400 according to the modified example of the third embodiment further includes a charge-blocking layer 432 and a charge-blocking layer 433 and is different in this point from the photoelectric conversion element 300 according to the third embodiment.

The charge-blocking layer 432 is located between the electrode 130 and the photosensitive layer 310. The charge-blocking layer 433 is located between the electrode 131 and the photosensitive layer 310.

As described above, one of a pair of hole and electron generated in the semiconducting carbon nanotube 312 of the photosensitive layer 310 is collected by the electrode 130, and the other is collected by the electrode 131. At this time, an electric charge with opposite polarity to an electric charge collected by the electrodes 130 and 131 may be injected into the photosensitive layer 310 from the electrodes 130 and 131. An electron and a hole that are electric charges injected from the electrodes 130 and 131 can recombine in the photosensitive layer 310. Consequently, an electric current called a dark current flows regardless of the incidence of light, and the dark current becomes noise to a signal of an electric current flowing in response to light. The charge-blocking layers 432 and 433 can reduce the dark current by reducing the injection of an electric charge from the electrodes 130 and 131 into the photosensitive layer 310.

One of the charge-blocking layers 432 and 433 is a hole-blocking layer, and the other is an electron-blocking layer.

The hole-blocking layer is disposed on the side of the electrode 130 or 131 that collects an electron with respect to the photosensitive layer 310. The electron affinity of the hole-blocking layer is, for example, close to the work function of the electrode, and the extraction of an electron by the electrode is therefore not easily inhibited. Furthermore, the ionization potential of the hole-blocking layer is, for example, higher than the work function of the electrode and therefore becomes a barrier to the injection of a hole from the electrode. A material of the hole-blocking layer is, for example, an organic or inorganic n-type semiconductor, a metal oxide, or the like having such an energy band structure. Specific examples of a material of the hole-blocking layer include n-type oxide semiconductors, such as ZnO, TiO₂, and SnO₂, and fullerenes and fullerene derivatives, such as C60, PCBM (phenyl C₆₁ butyric acid methyl ester), and PCBM (phenyl C₇₁ butyric acid methyl ester).

The electron-blocking layer is disposed on the side of the electrode 130 or 131 that collects a hole with respect to the photosensitive layer 310. The ionization potential of the electron-blocking layer is, for example, close to the work function of the electrode, and the extraction of a hole by the electrode is therefore not easily inhibited. Furthermore, the electron affinity of the electron-blocking layer is, for example, lower than the work function of the electrode and therefore becomes a barrier to the injection of an electron from the electrode. A material of the electron-blocking layer is, for example, an organic or inorganic p-type semiconductor, a metal oxide, or the like having such an energy band structure. Specific examples of a material of the electron-blocking layer include p-type semiconductors with a triphenylamine skeleton, such as VNPB ([N4,N4′-di(naphthalen-1-yl)-N4,N4′-bis(4-vinylphenyl)biphenyl-4,4′-diamine]) and poly-TPD (poly[N,N′-bis(4-butylphenyl)-N,N′-bis(phenyl)-benzidine]), p-type semiconductors with a triphenylamine skeleton and a fluorene skeleton, such as VB—FNPD9,9-bis[4-[(4-ethenylphenyl)methoxy]phenyl]-N2,N7-di-1-naphthalenyl-N2,N7-diphenyl-9H-fluorene-2,7-diamine and TFB (poly[(9,9-dioctylfluorenyl-2,7-diyl)-co-(4,4′-(N-(4-sec-butylphenyl)diphenylamine)]), and p-type semiconductors of a monovalent copper compounds, such as CuI and CuSCN.

When the quantum dot 311 has a higher electron affinity than the semiconducting carbon nanotube 312, for example, an electron is collected by the electrode 130, and a hole is collected by the electrode 131, so that the charge-blocking layer 432 is a hole-blocking layer, and the charge-blocking layer 433 is an electron-blocking layer. Consequently, the injection of a hole from the electrode 130 into the photosensitive layer 310 is suppressed by the charge-blocking layer 432, and the injection of an electron from the electrode 131 into the photosensitive layer 310 is suppressed by the charge-blocking layer 433.

When the quantum dot 311 has a lower ionization potential than the semiconducting carbon nanotube 312, for example, a hole is collected by the electrode 130, and an electron is collected by the electrode 131, so that the charge-blocking layer 432 is an electron-blocking layer, and the charge-blocking layer 433 is a hole-blocking layer. Consequently, the injection of an electron from the electrode 130 into the photosensitive layer 310 is suppressed by the charge-blocking layer 432, and the injection of a hole from the electrode 131 into the photosensitive layer 310 is suppressed by the charge-blocking layer 433.

The photoelectric conversion element 400 may include only one of the charge-blocking layers 432 and 433. Furthermore, the photoelectric conversion element 100 or the photoelectric conversion element 200 may include at least one of the charge-blocking layers 432 and 433.

### Fourth Embodiment

Next, a fourth embodiment is described. The fourth embodiment describes an imaging apparatus using the photoelectric conversion element according to the third embodiment. In the imaging apparatus according to the fourth embodiment, the photoelectric conversion element according to any one of the first embodiment, the second embodiment, and the modified example of the third embodiment may be used instead of the photoelectric conversion element according to the third embodiment. In the following description of the fourth embodiment, points of difference from the first to third embodiments and the modified example of the third embodiment are mainly described, and common features are not described or simply described.

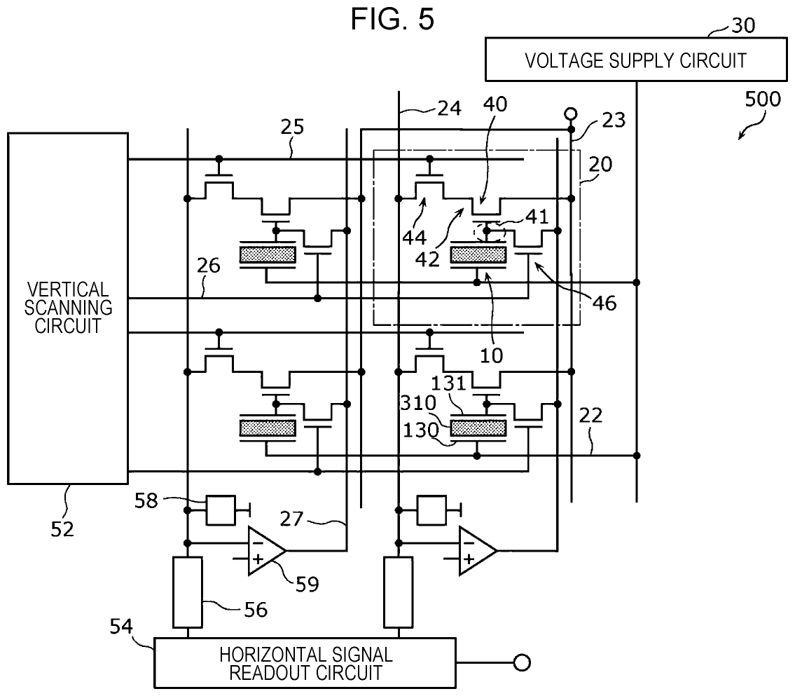

First, the overall configuration of the imaging apparatus according to the fourth embodiment is described. FIG. 5 is a view of an example of the circuitry of an imaging apparatus 500 according to the present embodiment. The imaging apparatus 500 illustrated in FIG. 5 includes a plurality of pixels 20 and a peripheral circuit. The peripheral circuit includes a voltage supply circuit 30 for supplying a predetermined voltage to each of the pixels 20.

The pixels 20 are one or two dimensionally arranged on a semiconductor substrate to form a photosensitive region, that is, a so-called pixel region. In the configuration illustrated in FIG. 5, the pixels 20 are arranged in a row direction and in a column direction. The terms “row direction” and “column direction”, as used herein, refer to the extending direction of a row and the extending direction of a column, respectively. More specifically, the longitudinal direction in the drawing of FIG. 5 is the column direction, and the transverse direction is the row direction. FIG. 5 illustrates four pixels 20 arranged in a 2×2 matrix. The number of pixels 20 illustrated in FIG. 5 is only an example for description, and the number of pixels 20 is not limited to four. When the pixels 20 are one dimensionally arranged, the imaging apparatus 500 is a line sensor.

Each of the pixels 20 has a photoelectric conversion portion 10 and a signal detection circuit 40 for detecting a signal generated by the photoelectric conversion portion 10. The photoelectric conversion portion 10 includes the electrode 130, the electrode 131, and a photosensitive layer 310 between the electrode 130 and the electrode 131. The photoelectric conversion portion 10 is composed of, for example, the photoelectric conversion element 300 according to the third embodiment.

The electrode 131 functions as a charge collector. As illustrated in FIG. 5, the electrode 130 is coupled to the voltage supply circuit 30 via a storage control line 22. When the imaging apparatus 500 is operated, a predetermined bias voltage is applied to the electrode 130 via the storage control line 22. The electrode 131 is also referred to as a pixel electrode, and the electrode 130 is also referred to as a counter electrode facing the pixel electrode.

The photoelectric conversion portion 10 is configured to collect as a signal charge by the electrode 131 either a hole (in other words, a positive charge) or an electron (in other words, a negative charge) from a pair of electron and hole generated by photoelectric conversion in the photosensitive layer 310. The electric potential of the electrode 130 can be controlled using a bias voltage generated by the voltage supply circuit 30 to collect any one of a hole and an electron by the electrode 131.

For example, when a hole is used as a signal charge, the voltage supply circuit 30 applies a voltage to the electrode 130 via the storage control line 22 such that the electrode 130 has a higher electric potential than the electrode 131. In this case, the photosensitive layer 310 includes the quantum dot 311 and the semiconducting carbon nanotube 312 such that the quantum dot 311 has a higher electron affinity than the semiconducting carbon nanotube 312.

For example, when an electron is used as a signal charge, the voltage supply circuit 30 applies a voltage to the electrode 130 via the storage control line 22 such that the electrode 130 has a lower electric potential than the electrode 131. In this case, the photosensitive layer 310 includes the quantum dot 311 and the semiconducting carbon nanotube 312 such that the quantum dot 311 has a lower ionization potential than the semiconducting carbon nanotube 312.

The voltage supply circuit 30 applies a voltage of, for example, approximately 10 V in absolute value to the electrode 130.

In the configuration illustrated in FIG. 5, the signal detection circuit 40 includes an amplifying transistor 42, an address transistor 44, and a reset transistor 46. The amplifying transistor 42 is also referred to as a charge detection transistor, and the address transistor 44 is also referred to as a row selection transistor. Typically, the amplifying transistor 42 and the address transistor 44 are field-effect transistors (FETs) formed on a semiconductor substrate. In an example described below, an N-channel metal oxide semiconductor field effect transistor (MOSFET) is used as a transistor, unless otherwise specified. The amplifying transistor 42, the address transistor 44, and the reset transistor 46 have a control terminal, an input terminal, and an output terminal. The control terminal is, for example, a gate. The input terminal is one of a drain and a source, typically a drain. The output terminal is the other of a drain and a source, typically a source.

The “semiconductor substrate” in the present specification is not limited to a substrate composed entirely of a semiconductor but may be an insulating substrate including a semiconductor layer on a surface on which the photosensitive region is formed. The semiconductor substrate is, for example, a p-type silicon substrate.

As illustrated in FIG. 5, one of the input terminal and the output terminal of the amplifying transistor 42 is connected to one of the input terminal and the output terminal of the address transistor 44. The control terminal of the amplifying transistor 42 is electrically connected to the electrode 131 of the photoelectric conversion portion 10. A signal charge collected by the electrode 131 is stored in a charge storage node 41 between the electrode 131 and the gate of the amplifying transistor 42. The signal charge is a hole or an electron. The charge storage node 41 is an example of a charge storage portion and is also referred to as a “floating diffusion node”.

A voltage corresponding to a signal charge stored in the charge storage node 41 is applied to the gate of the amplifying transistor 42. The amplifying transistor 42 amplifies this voltage. In other words, the amplifying transistor 42 amplifies a signal generated by the photoelectric conversion portion 10. The voltage amplified by the amplifying transistor 42 is selectively read out as a signal voltage via the address transistor 44. One of the source and the drain of the reset transistor 46 is coupled to the charge storage node 41, and one of the source and the drain of the reset transistor 46 has an electrical connection with the electrode 131.

The reset transistor 46 resets a signal charge stored in the charge storage node 41. In other words, the reset transistor 46 resets the electric potential of the gate of the amplifying transistor 42 and the electrode 131.

As illustrated in FIG. 5, the imaging apparatus 500 includes a power supply line 23, a vertical signal line 24, an address signal line 25, and a reset signal line 26. These lines are connected to each of the pixels 20. The power supply line 23 is connected to one of the source and the drain of the amplifying transistor 42 and supplies a predetermined supply voltage to each of the pixels 20. The power supply line 23 functions as a source follower power supply. The vertical signal line 24 is connected to one of the source and the drain of the address transistor 44 that is not connected to the source or the drain of the amplifying transistor 42. The address signal line 25 is connected to the gate electrode of the address transistor 44. The reset signal line 26 is connected to the gate of the reset transistor 46.

A peripheral circuit of the imaging apparatus 500 includes a vertical scanning circuit 52, a horizontal signal readout circuit 54, a plurality of column signal processing circuits 56, a plurality of load circuits 58, and a plurality of inverting amplifiers 59. The vertical scanning circuit 52 is also referred to as a “row scanning circuit”, the horizontal signal readout circuit 54 is also referred to as a “column scanning circuit”, and the column signal processing circuits 56 are also referred to as “row signal storage circuits”. The column signal processing circuits 56, the load circuits 58, and the inverting amplifiers 59 are provided corresponding to each column of the plurality of pixels 20 arranged in the row direction and in the column direction. Each of the column signal processing circuits 56 is electrically connected to the pixel 20 arranged in each column via the vertical signal line 24 corresponding to each column of the plurality of pixels 20. The plurality of column signal processing circuits 56 are electrically connected to the horizontal signal readout circuit 54. Each of the load circuits 58 is electrically connected to the vertical signal line 24, and the load circuits 58 and the amplifying transistor 42 form a source follower circuit.

The vertical scanning circuit 52 is connected to the address signal line 25 and the reset signal line 26. The vertical scanning circuit 52 applies a row selection signal for controlling ON and OFF of the address transistor 44 to the gate of the address transistor 44 via the address signal line 25. The row selection signal is transmitted to each address signal line 25 to scan and select a row to be read out. A signal voltage is read from the pixels 20 of the selected row to the vertical signal line 24. The vertical scanning circuit 52 applies a reset signal for controlling ON and OFF of the reset transistor 46 to the gate of the reset transistor 46 via the reset signal line 26. A row selection signal is transmitted to each reset signal line 26 to select a row of pixels 20 to be reset. In this manner, the vertical scanning circuit 52 selects the plurality of pixels 20 on a row-by-row basis, reads the signal voltage, and resets the electric potential of the electrode 131.

A signal voltage read from the pixel 20 selected by the vertical scanning circuit 52 is transmitted to the column signal processing circuits 56 via the vertical signal line 24. The column signal processing circuits 56 perform noise suppression signal processing exemplified by correlated double sampling and analog-to-digital conversion (AD conversion). The horizontal signal readout circuit 54 sequentially reads a signal from the plurality of column signal processing circuits 56 to a horizontal common signal line (not shown).

The vertical scanning circuit 52 may partially include the voltage supply circuit 30. Alternatively, the voltage supply circuit 30 may have an electrical connection with the vertical scanning circuit 52. In other words, a bias voltage may be applied to the electrode 130 via the vertical scanning circuit 52.

In the configuration illustrated in FIG. 5, the inverting amplifier 59 is provided in each column. A negative input terminal of the inverting amplifier 59 is connected to the corresponding vertical signal line 24. An output terminal of the inverting amplifier 59 is connected to each pixel 20 of the corresponding column via a feedback line 27 of the column.

As illustrated in FIG. 5, the feedback line 27 is connected to one (for example, the drain) of the source and the drain of the reset transistor 46 that is not connected to the charge storage node 41. Thus, when the address transistor 44 and the reset transistor 46 are in a conductive state, the inverting amplifier 59 receives the output of the address transistor 44 at the negative terminal. On the other hand, a reference voltage at reset is applied from a power supply (not shown) to the positive input terminal of the inverting amplifier 59. The inverting amplifier 59 performs a feedback operation so that the gate voltage of the amplifying transistor 42 reaches a predetermined feedback voltage. The feedback voltage means the output voltage of the inverting amplifier 59. The output voltage of the inverting amplifier 59 is, for example, 0 V or a positive voltage close to 0 V. The inverting amplifier 59 may be referred to as a “feedback amplifier”.

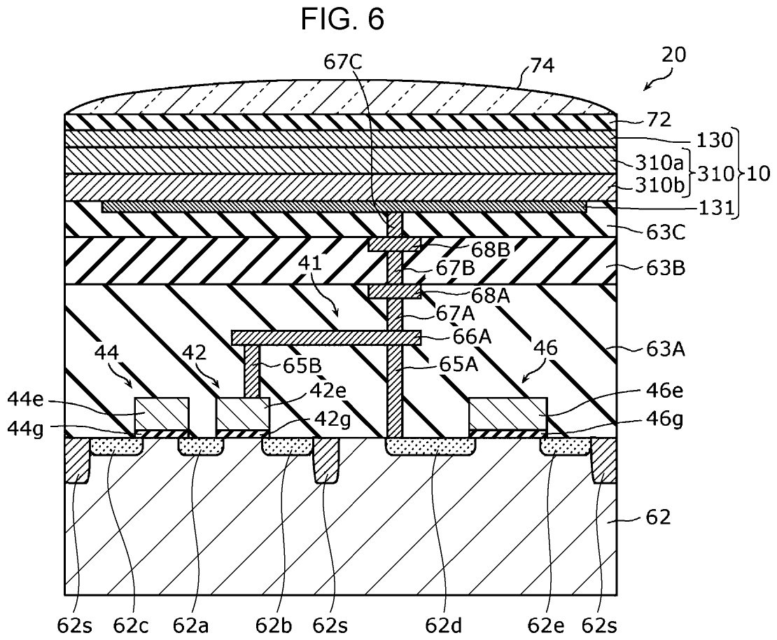

FIG. 6 is a schematic view of a cross section of a device structure of the pixel 20 in the imaging apparatus 500 according to the present embodiment. In the configuration illustrated in FIG. 6, the pixel 20 includes a semiconductor substrate 62 that supports the photoelectric conversion portion 10. The semiconductor substrate 62 is, for example, a silicon substrate. As illustrated in FIG. 6, the photoelectric conversion portion 10 is disposed above the semiconductor substrate 62. In the imaging apparatus 500, light enters the photoelectric conversion portion 10 from above the photoelectric conversion portion 10. In this example, interlayer insulating layers 63A, 63B, and 63C are stacked on the semiconductor substrate 62, and a laminate of the electrode 131, the photosensitive layer 310, and the electrode 130 is disposed on the interlayer insulating layer 63C. The electrode 131 is partitioned for each pixel and is spatially separated between two adjacent pixels 20, and two adjacent electrodes 131 are therefore electrically isolated. The photosensitive layer 310 and the electrode 130 may be formed over a plurality of pixels 20.

The amplifying transistor 42, the address transistor 44, and the reset transistor 46 are formed on the semiconductor substrate 62.

The amplifying transistor 42 includes impurity regions 62a and 62b formed in the semiconductor substrate 62, a gate-insulating layer 42g located on the semiconductor substrate 62, and a gate electrode 42e located on the gate-insulating layer 42g. The impurity regions 62a and 62b function as the drain or the source of the amplifying transistor 42. The impurity regions 62a and 62b and impurity regions 62c, 62d, and 62e described later are, for example, n-type impurity regions.

The address transistor 44 includes the impurity regions 62a and 62c formed in the semiconductor substrate 62, a gate-insulating layer 44g located on the semiconductor substrate 62, and a gate electrode 44e located on the gate-insulating layer 44g. The impurity regions 62a and 62c function as the drain or the source of the address transistor 44. In this example, the amplifying transistor 42 and the address transistor 44 share the impurity region 62a, so that the source (or drain) of the amplifying transistor 42 is electrically connected to the drain (or source) of the address transistor 44.

The reset transistor 46 includes the impurity regions 62d and 62e formed in the semiconductor substrate 62, a gate-insulating layer 46g located on the semiconductor substrate 62, and a gate electrode 46e located on the gate-insulating layer 46g. The impurity regions 62d and 62e function as the drain or the source of the reset transistor 46.

In the semiconductor substrate 62, an element isolation region 62s is provided between adjacent pixels 20 and between the amplifying transistor 42 and the reset transistor 46. The element isolation region 62s electrically separates adjacent pixels 20 from each other. Furthermore, the element isolation region 62s between adjacent pixels 20 reduces the leakage of a signal charge stored in the charge storage node 41.

In the interlayer insulating layer 63A, a contact plug 65A connected to the impurity region 62d of the reset transistor 46, a contact plug 65B connected to the gate electrode 42e of the amplifying transistor 42, and a wire 66A connecting the contact plug 65A and the contact plug 65B are formed. Thus, the impurity region 62d (for example, the drain) of the reset transistor 46 is electrically connected to the gate electrode 42e of the amplifying transistor 42. In the configuration illustrated in FIG. 6, a plug 67A and a wire 68A are further formed in the interlayer insulating layer 63A. A plug 67B and a wire 68B are formed in the interlayer insulating layer 63B, a plug 67C is formed in the interlayer insulating layer 63C, and the wire 66A is therefore electrically connected to the electrode 131. The contact plug 65A, the contact plug 65B, the wire 66A, the plug 67A, the wire 68A, the plug 67B, the wire 68B, and the plug 67C are typically made of metal.

In the configuration illustrated in FIG. 6, a protective layer 72 is disposed on the electrode 130. The protective layer 72 is not a substrate arranged to support the photoelectric conversion portion 10. The protective layer 72 is a layer for protecting and insulating the photoelectric conversion portion 10 from others. The protective layer 72 may be highly transparent or translucent at a specific wavelength. A material of the protective layer 72 may be a transparent or translucent insulator and is, for example, SiON or AlO. As illustrated in FIG. 6, a microlens 74 may be disposed on the protective layer 72.

In the present embodiment, the photoelectric conversion portion 10 is an example of a photoelectric conversion element and is constituted by the photoelectric conversion element according to the third embodiment. For example, as illustrated in FIG. 6, the photoelectric conversion portion 10 has the same structure as the photoelectric conversion element 300. The electrode 130 is disposed above the photosensitive layer 310, in other words, on the side of the photosensitive layer 310 from which light enters the imaging apparatus 500. Light enters the photosensitive layer 310 through the electrode 130. In the present embodiment, the electrode 130 is, for example, a transparent electrode.

The photoelectric conversion portion 10 may have a structure in which the positions of the electrodes 130 and 131 are reversed. In other words, the photoelectric conversion portion 10 has a configuration in which the electrode 130, the quantum dot layer 310a, the semiconducting carbon nanotube layer 310b, and the electrode 131 are stacked in this order from the semiconductor substrate 62 side, the electrode 130 may function as a pixel electrode, and the electrode 131 may function as a counter electrode. The photoelectric conversion portion 10 may have the same structure as the photoelectric conversion element 100, the photoelectric conversion element 200, or the photoelectric conversion element 400. Also in this case, the electrode 131 may be disposed on the semiconductor substrate 62 side of the photoelectric conversion portion 10, or the electrode 130 may be disposed on the semiconductor substrate 62 side of the photoelectric conversion portion 10.

The imaging apparatus 500 as described above can be produced by a typical semiconductor production process. In particular, when the semiconductor substrate 62 is a silicon substrate, the imaging apparatus 500 can be produced by utilizing various silicon semiconductor processes.

### Examples

Next, the present disclosure is more specifically described on the basis of examples. The present disclosure is not limited in any way by these examples.

### [Production of Photoelectric Conversion Element]

A photoelectric conversion element used in an example was prepared by the following method.

A xylene solution of [N4,N4′-di(naphthalen-1-yl)-N4,N4′-bis(4-vinylphenyl)biphenyl-4,4′-diamine] (abbreviated as VNPB) was applied as a material for an electron-blocking layer by spin coating to an ITO electrode of a glass substrate having the ITO electrode as an electrode for transmitting light of a specific wavelength formed on the upper surface thereof. After the solvent of the coating solution was volatilized at 110° C., VNPB was polymerized by heating at 230° C. to make it insoluble in the solvent.

Next, a carbon nanotube (trade name SG65i) purchased from Sigma-Aldrich Corporation and poly(9,9-dioctyl-9H-fluorene-2,7-diyl) (abbreviated as PFO) were mixed in toluene, and after ultrasonic homogenizer treatment, the supernatant of centrifugation treatment was separated to collect the carbon nanotube covered with PFO and dispersed in the solvent. After excess PFO was removed by filtration through a filter, the product was re-dispersed in toluene to prepare a dispersion liquid of a semiconducting carbon nanotube containing a semiconducting carbon nanotube of chirality (7,5) as the main component and partially mixed with a semiconducting carbon nanotube of chirality (7,6).

The semiconducting carbon nanotube dispersion liquid was applied to the insolubilized VNPB serving as an electron-blocking layer to form a semiconducting carbon nanotube layer with a thickness of approximately 20 nm. A solution of an oleic-acid-coated PbS quantum dot purchased from Quantum Solutions was spin-coated on the semiconducting carbon nanotube layer, and the ligand was then substituted by a solid-phase substitution method to form a quantum dot layer.

Next, a ZnO nanoparticle ink purchased from Avantama was applied by spin coating to form a hole-blocking layer. An aluminum (Al) electrode was then formed on the hole-blocking layer in a vacuum evaporator to prepare a photoelectric conversion element.

In the preparation of the photoelectric conversion element described above, a plurality of photoelectric conversion elements were prepared using quantum dots 1 to 4. The electron affinity and ionization potential of the quantum dots were adjusted by changing the particle size of the quantum dots and the ligand to be substituted. Table 1 shows the light absorption peak wavelength, the substituted ligand, the electron affinity, and the ionization potential of each quantum dot with adjusted electron affinity and ionization potential. As described above, the light absorption peak wavelength of a quantum dot is also a factor indicating the particle size of the quantum dot.

The ionization potential was measured with a photoelectron spectrometer (AC-3, manufactured by Riken Keiki Co., Ltd.). The number of photoelectrons was measured when the energy of ultraviolet radiation was changed, and the energy position at which photoelectrons began to be detected was defined as ionization potential. In the measurement of the electron affinity, first, an absorption spectrum of a quantum dot was measured, and the optical band gap was calculated from the result of an absorption edge of the absorption spectrum. The electron affinity was then calculated from the ionization potential measured by the above method and the calculated optical band gap.

In the description of the examples and the drawings used for the description of the examples, the quantum dots 1 to 4 may be referred to as QD1 to QD4, respectively. The semiconducting carbon nanotube is sometimes referred to as CNT.

TABLE 1

| | Light | | | |
|---|---|---|---|---|
| | absorption | | | |
| | peak | | Electron | Ionization |
| | wavelength | | affinity | potential |
| Quantum dot | [nm] | Ligand | [eV] | [eV] |
| Quantum dot 1 | 1000 | 1,2-ethanedithiol | −3.8 | −5.0 |
| (QD1) | | | | |
| Quantum dot 2 | 1000 | 1,4-benzenedithiol | −4.1 | −5.3 |
| (QD2) | | | | |
| Quantum dot 3 | 1200 | 1,4-benzenedithiol | −4.3 | −5.3 |
| (QD3) | | | | |
| Quantum dot 4 | 1400 | 1,4-benzenedithiol | −4.5 | −5.3 |
| (QD4) | | | | |

The semiconducting carbon nanotube of chirality (7,5) has a light absorption peak wavelength of 1040 nm, and the semiconducting carbon nanotube of chirality (7,6) has a light absorption peak wavelength of 1150 nm.

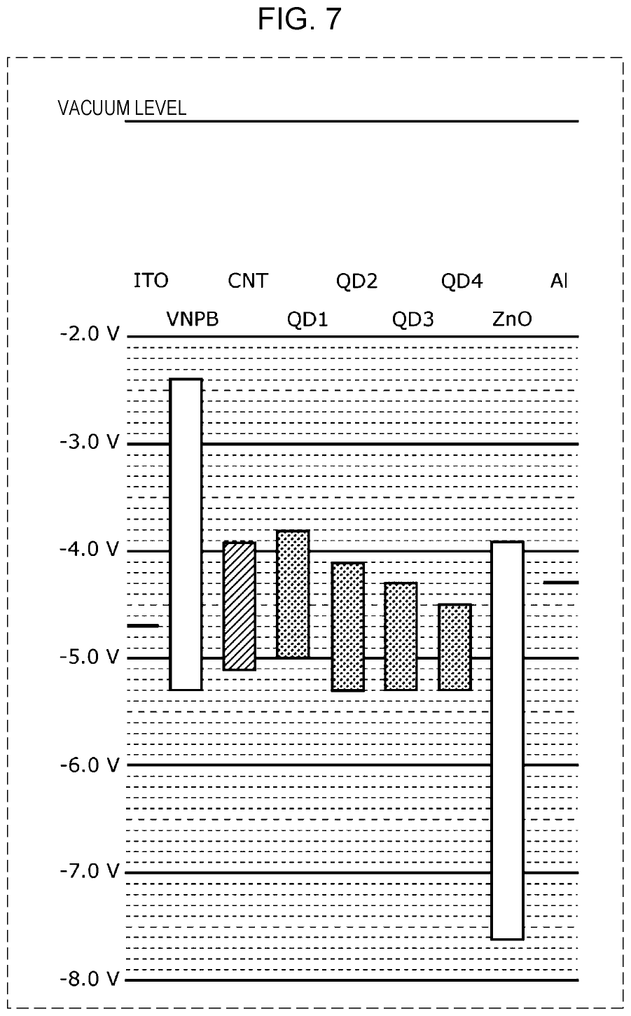

FIG. 7 shows the work functions of the ITO electrode and the aluminum (Al) electrode, and the energy levels of the quantum dot 1 (QD1) to the quantum dot 4 (QD4), the semiconducting carbon nanotube (CNT), the electron-blocking layer VNPB, and the hole-blocking layer ZnO.

As shown in Table 1 and FIG. 7, each quantum dot has the same ionization potential when the ligand is the same. Furthermore, the band gap of the quantum dot decreases as the particle size of the quantum dot increases and as the light absorption peak wavelength increases. Thus, when the ligand is the same, the electron affinity of the quantum dot increases with the particle size of the quantum dot.

In the photoelectric conversion element thus prepared, a semiconducting carbon nanotube layer and a quantum dot layer are stacked as a photosensitive layer, an electron-blocking layer composed of VNPB is located between the semiconducting carbon nanotube layer and the ITO electrode, and a hole-blocking layer composed of ZnO is located between the quantum dot layer and an Al electrode. Thus, in the photoelectric conversion element, the quantum dot extracts an electron from the semiconducting carbon nanotube, a hole remains in the semiconducting carbon nanotube, and these electric charges are extracted from the electrodes through the charge-blocking layers.

### [Evaluation of Spectral Sensitivity Characteristics]

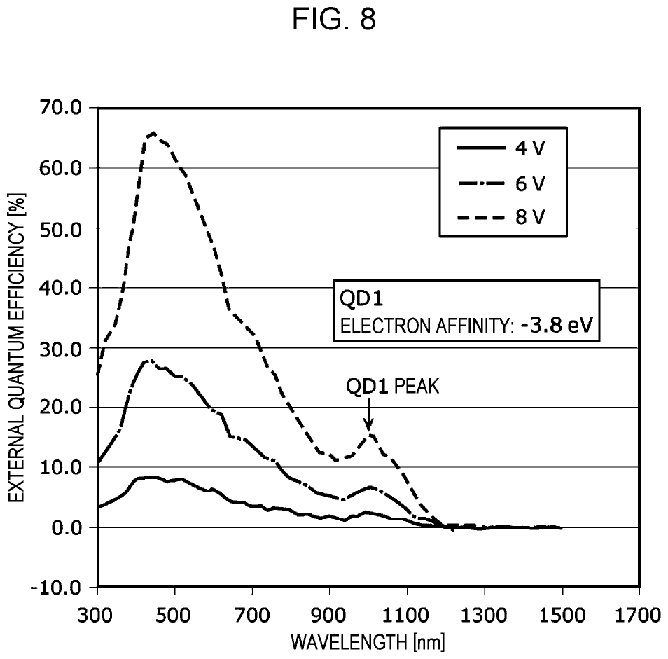

The spectral sensitivity characteristics of a photoelectric conversion element were evaluated to compare the efficiency of a quantum dot extracting an electron from a semiconducting carbon nanotube due to the magnitude relation of electron affinity between the semiconducting carbon nanotube and the quantum dot. More specifically, the external quantum efficiency (EQE) was measured as the spectral sensitivity of the photoelectric conversion elements containing the quantum dots 1 to 4. A long-wavelength responsive spectral sensitivity measuring apparatus (CEP-25RR manufactured by Bunkoukeiki Co., Ltd.) was used to measure the external quantum efficiency. The external quantum efficiency was measured in a nitrogen atmosphere. In the measurement of the external quantum efficiency, a voltage was applied between an ITO electrode and an Al electrode such that the electric potential of the Al electrode was positive with respect to the electric potential of the ITO electrode. FIGS. 8 to 11 show the measurement results. The numerical values shown in the legends of FIGS. 8 to 11 indicate the voltages applied in the measurement of the external quantum efficiency.

FIG. 8 shows measurement results of the spectral sensitivity characteristics of a photoelectric conversion element containing the quantum dot 1 (QD1). As shown in FIG. 8, the photoelectric conversion element containing QD1 has a spectral sensitivity response with a peak at 1000 nm. Furthermore, no spectral sensitivity response is observed at 1150 nm, which is a light absorption peak wavelength of the semiconducting carbon nanotube of chirality (7,6). QD1 has a light absorption peak wavelength of 1000 nm, and the spectral sensitivity response with a peak at 1000 nm is therefore considered to be a spectral sensitivity response derived from the light absorption of QD1. It is judged from this that only the spectral sensitivity response derived from the light absorption of QD1 was obtained and the spectral sensitivity response derived from the light absorption of the semiconducting carbon nanotube was not obtained.

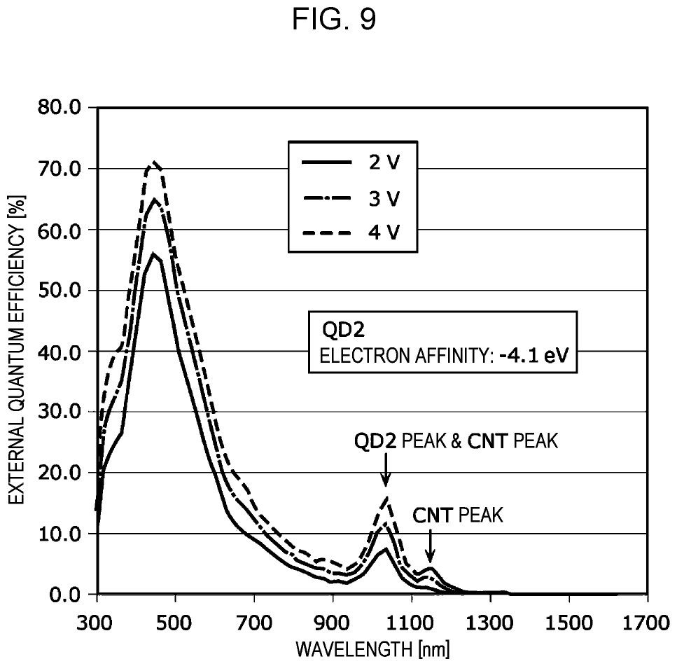

FIG. 9 shows measurement results of the spectral sensitivity characteristics of a photoelectric conversion element containing the quantum dot 2 (QD2). As shown in FIG. 9, the photoelectric conversion element containing QD2 has a spectral sensitivity response with a peak at approximately 1000 nm and 1150 nm. Thus, a spectral sensitivity response is observed at 1150 nm, which is a light absorption peak wavelength of the semiconducting carbon nanotube of chirality (7,6). The semiconducting carbon nanotube is composed mainly of the semiconducting carbon nanotube of chirality (7,5). The semiconducting carbon nanotube of chirality (7,5) has a light absorption peak wavelength of 1040 nm, and QD2 has a light absorption peak wavelength of 1000 nm. It is judged from these that the spectral sensitivity response with a peak around 1000 nm overlaps the spectral sensitivity response derived from the light absorption of QD2 and the spectral sensitivity response derived from the light absorption of the semiconducting carbon nanotube of chirality (7,5). It is therefore judged that the photoelectric conversion element containing QD2 has the spectral sensitivity response derived from the light absorption of the semiconducting carbon nanotube.

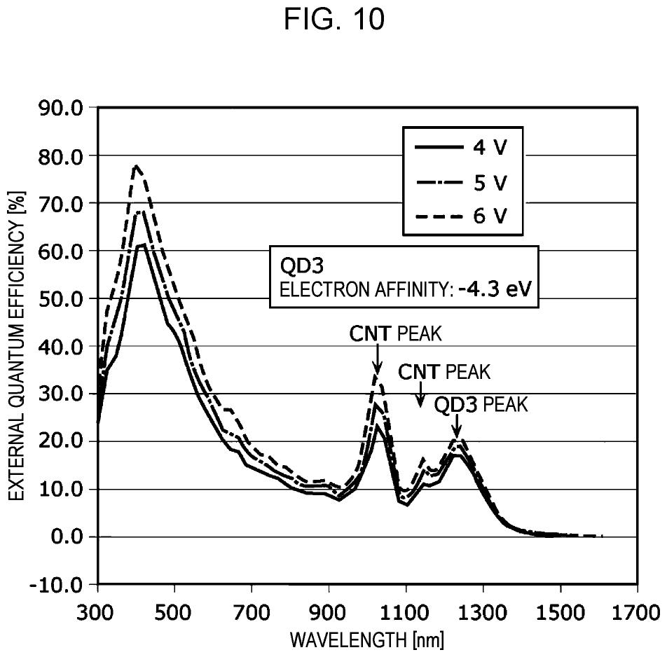

FIG. 10 shows measurement results of the spectral sensitivity characteristics of a photoelectric conversion element containing the quantum dot 3 (QD3). As shown in FIG. 10, the photoelectric conversion element containing QD3 has spectral sensitivity responses with peaks at 1040 nm, 1150 nm, and 1200 nm corresponding to the light absorption peak wavelengths of the semiconducting carbon nanotube of chirality (7,5), the semiconducting carbon nanotube of chirality (7,6), and QD3, respectively. The photoelectric conversion element containing QD3 has an external quantum efficiency of 30% or more at 1040 nm, which exceeds the external quantum efficiency derived from the light absorption of QD3 at 1200 nm, due to the light absorption of the semiconducting carbon nanotube of chirality (7,5). Furthermore, an external quantum efficiency of 10% or more is obtained at 1150 nm due to the light absorption of the semiconducting carbon nanotube of chirality (7,6).

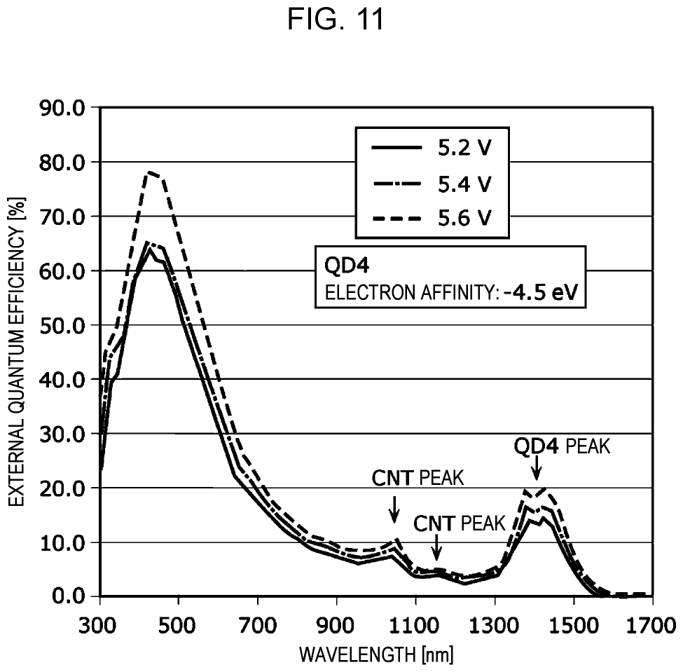

FIG. 11 shows measurement results of the spectral sensitivity characteristics of a photoelectric conversion element containing the quantum dot 4 (QD4). As shown in FIG. 11, the photoelectric conversion element containing QD4 has spectral sensitivity responses with peaks at 1040 nm, 1150 nm, and 1400 nm corresponding to the light absorption peak wavelengths of the semiconducting carbon nanotube of chirality (7,5), the semiconducting carbon nanotube of chirality (7,6), and QD4, respectively. The external quantum efficiency at 1040 nm and 1150 nm derived from the light absorption of the semiconducting carbon nanotube is lower in the photoelectric conversion element containing QD4 than in the photoelectric conversion element containing QD3.

It can be confirmed from these results that a quantum dot with a higher electron affinity than a semiconducting carbon nanotube can extract an electron from the semiconducting carbon nanotube.

Although a quantum dot with a higher electron affinity than a semiconducting carbon nanotube can extract an electron from the semiconducting carbon nanotube, the photoelectric conversion element containing QD4, which has the largest difference in electron affinity between the quantum dot and the semiconducting carbon nanotube, has a lower external quantum efficiency than the photoelectric conversion element containing QD3. This is probably because the valence band of the quantum dot deeper than the center (−4.5 eV) of the band gap of the semiconducting carbon nanotube in the examples is closer to the valence band than to the conduction band of the semiconducting carbon nanotube and has a stronger interaction with the valence band than with the conduction band of the semiconducting carbon nanotube. Thus, it is thought that the electron affinity of the quantum dot smaller than the difference between the energy at the center of the band gap of the semiconducting carbon nanotube and the vacuum level increases the external quantum efficiency.

### Other Embodiments

Although a photoelectric conversion element and an imaging apparatus according to the present disclosure have been described on the basis of the embodiments, modified examples, and examples, the present disclosure is not limited to these embodiments, modified examples, and examples. Without departing from the gist of the present disclosure, these embodiments, modified examples, and examples subjected to various modifications conceived by a person skilled in the art, and other embodiments constructed by combining constituents of the embodiments, modified examples, and examples are also fall within the scope of the present disclosure.

For example, a photoelectric conversion element according to the present disclosure may be used in a solar cell by extracting an electric charge generated by light as energy. A photoelectric conversion element according to the present disclosure may be used in an photosensor by extracting an electric charge generated by light as a signal.

A photoelectric conversion element, a method for driving the photoelectric conversion element, and the like according to the present disclosure can be used, for example, for an imaging apparatus and a photosensor of a camera. In particular, they can be used for a vehicle camera, a surveillance camera, a photosensor, and the like used in the near-infrared region.

What is claimed is:

1. A photoelectric conversion element comprising:
a first electrode;
a second electrode facing the first electrode; and
a photosensitive layer between the first electrode and the second electrode,
at least one selected from the group consisting of the first electrode and the second electrode transmits light,
the photosensitive layer contains a quantum dot and a semiconducting carbon nanotube that absorbs the light, and
the quantum dot has a higher absolute value of electron affinity than the semiconducting carbon nanotube.

2. The photoelectric conversion element according to claim 1, wherein
the photosensitive layer includes
a quantum dot layer containing the quantum dot, and
a semiconducting carbon nanotube layer located between the quantum dot layer and the second electrode and containing the semiconducting carbon nanotube.

3. A photoelectric conversion element comprising:
a first electrode;
a second electrode facing the first electrode; and
a photosensitive layer between the first electrode and the second electrode,
at least one selected from the group consisting of the first electrode and the second electrode transmits light,
the photosensitive layer contains a quantum dot and a semiconducting carbon nanotube that absorbs the light, and
the quantum dot has a lower absolute value of ionization potential than the semiconducting carbon nanotube.

4. The photoelectric conversion element according to claim 3, wherein
the photosensitive layer includes
a quantum dot layer containing the quantum dot, and
a semiconducting carbon nanotube layer located between the quantum dot layer and the second electrode and containing the semiconducting carbon nanotube.

5. The photoelectric conversion element according to claim 1, wherein
the photosensitive layer contains a polymer covering the semiconducting carbon nanotube.

6. The photoelectric conversion element according to claim 1, wherein
the semiconducting carbon nanotube in the photosensitive layer absorbs 10% or more of a component with a specific wavelength in the light.

7. The photoelectric conversion element according to claim 1, further comprising:
a charge-blocking layer between the first electrode or the second electrode and the photosensitive layer.

8. The photoelectric conversion element according to claim 1, wherein
the photoelectric conversion element has an external quantum efficiency of 10% or more at a light absorption peak wavelength of the semiconducting carbon nanotube.

9. The photoelectric conversion element according to claim 1, wherein
the photoelectric conversion element has an external quantum efficiency of 30% or more at a light absorption peak wavelength of the semiconducting carbon nanotube.

10. An imaging apparatus comprising:
a plurality of pixels,
wherein each of the plurality of pixels includes the photoelectric conversion element according to claim 1.

11. An imaging apparatus comprising:
a plurality of pixels,
wherein each of the plurality of pixels includes the photoelectric conversion element according to claim 3.

12. A method for driving the photoelectric conversion element according to claim 2, comprising:
setting an electric potential of the first electrode to be positive with respect to an electric potential of the second electrode; and
out of an electron and a hole generated by the semiconducting carbon nanotube absorbing light, collecting the electron through the quantum dot using the first electrode and collecting the hole using the second electrode.

13. A method for driving the photoelectric conversion element according to claim 4, comprising:
setting an electric potential of the first electrode to be negative with respect to an electric potential of the second electrode; and
out of an electron and a hole generated by the semiconducting carbon nanotube absorbing light, collecting the hole through the quantum dot using the first electrode and collecting the electron using the second electrode.
